(19) United States
(12) Patent Application Publication
(10) Pub. No.: US 2026/0032945 A1
(43) Pub. Date: Jan. 29, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chang-Yih Chen, Tainan City (TW); Kuo-Hsing Lee, Hsinchu County (TW); Chun-Hsien Lin, Tainan City (TW); Yi-Wen Chen, Chiayi County (TW); Chih-Kai Kang, Tainan City (TW); Sheng-Yuan Hsueh, Tainan City (TW); Yao-Jhan Wang, Tainan City (TW)

(73) Assignee: UNITED MICROELECTRONICS CORP., Hsin-Chu City (TW)

(21) Appl. No.: 18/810,538

(22) Filed: Aug. 21, 2024

(30) Foreign Application Priority Data
Jul. 26, 2024 (TW) 113127764

(51) Int. Cl. H01L 29/78; H01L 21/8234; H01L 29/423

(52) U.S. Cl. CPC H10D 30/62; H10D 64/512; H10D 84/0158; H10D 84/038

(57) ABSTRACT

A semiconductor device includes a first fin structure, an insulating structure and a gate structure. The first fin structure is disposed on a substrate. The insulating structure is disposed on the substrate and surrounding the first fin structure. The gate structure is disposed on the first fin structure. The gate structure includes a first extending portion disposed between the first fin structure and the insulating structure.

### BACKGROUND OF THE INVENTION

### 1. Field of the Invention

The present disclosure relates to the field of semiconductor devices, and more particularly, to a semiconductor device favorable for reducing noises and a method for fabricating the same.

### 2. Description of the Prior Art

In order to reduce production costs and improve competitive advantages, the dimensions of semiconductor devices are continued to be reduced. However, with the miniaturization of the semiconductor device, how to maintain the height of the gate structure of the semiconductor device in a limited volume has become a major challenge. When the height of the gate structure is low, the ability of the gate structure to control current is reduced, and the gate structure cannot effectively control on and off of the transistor. Accordingly, it is unfavorable for reducing the noises of the semiconductor device.

### SUMMARY OF THE INVENTION

According to an embodiment of the present disclosure, a semiconductor device includes a first fin structure, an insulating structure and a gate structure. The first fin structure is disposed on a substrate. The insulating structure is disposed on the substrate and surrounding the first fin structure. The gate structure is disposed on the first fin structure. The gate structure includes a first extending portion disposed between the first fin structure and the insulating structure.

According to another embodiment of the present disclosure, a method for fabricating a semiconductor device includes steps as follows. A first fin structure is formed on a substrate. An insulating structure is formed on the substrate and surrounding the first fin structure. A gate structure is formed on the first fin structure. The gate structure includes a first extending portion disposed between the first fin structure and the insulating structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6 and FIG. 7 are schematic diagrams showing steps for fabricating a semiconductor device according to one embodiment of the present disclosure.

FIG. 8 is a schematic view of a semiconductor device according to another embodiment of the present disclosure.

FIG. 9 is a schematic view of a semiconductor device according to further another embodiment of the present disclosure.

FIG. 10 is a schematic view of a semiconductor device according to yet another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

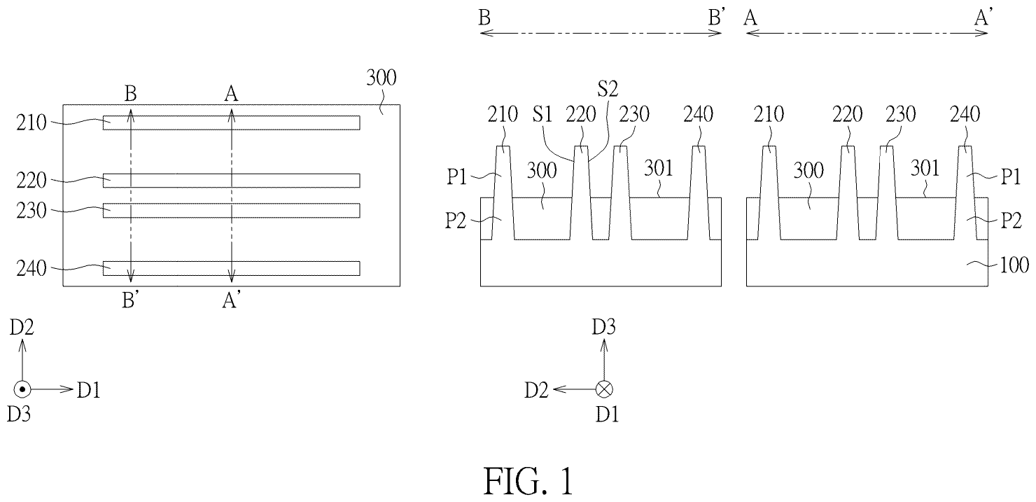

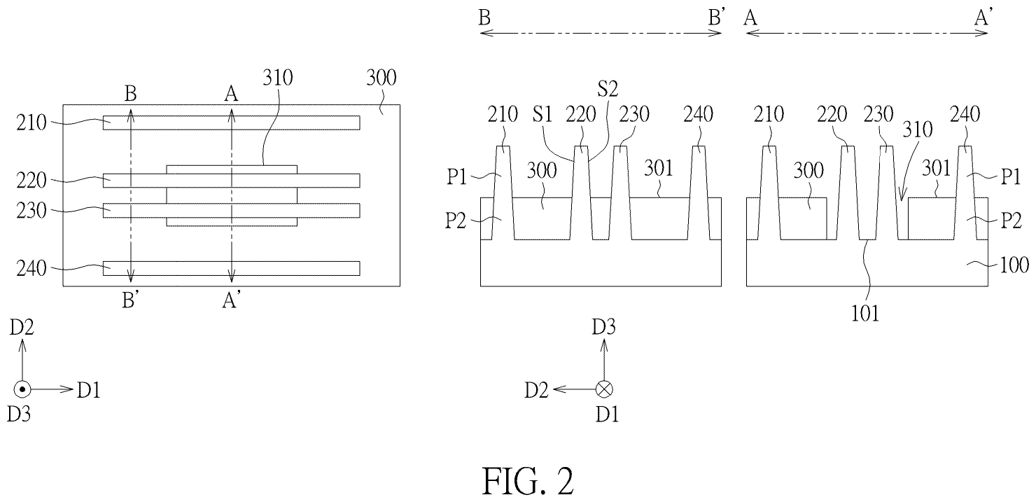

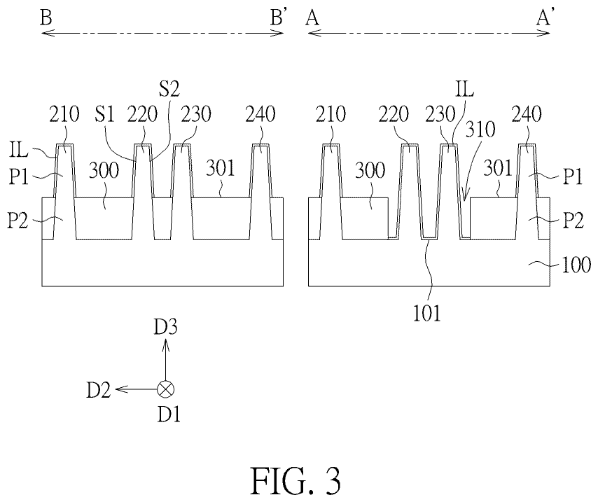

Please refer to FIG. 1 to FIG. 7, which are schematic diagrams showing steps for fabricating a semiconductor device 10 (see FIG. 7) according to one embodiment of the present disclosure. In FIG. 1, the left portion shows a schematic top view of a semi-finished semiconductor device, and the right portion from left to right shows schematic cross-sectional views taken along line B-B′ and line A-A′ in the left portion. First, at least one fin structure 210, 220, 230 or 240 is formed on a substrate 100. Herein, four fin structures 210, 220, 230 and 240 are exemplarily formed on the substrate 100. The substrate 100 may be a semiconductor substrate, such as a silicon substrate, an epitaxial silicon substrate, a silicon carbide substrate or a silicon on insulator (SOI) substrate. The fin structures 210, 220, 230 and 240 may be formed by methods as follows. For example, a patterned mask (not shown) is formed on the substrate 100, and then an etching process is performed to transfer the pattern of the patterned mask to the substrate 100 to form the fin structures 210, 220, 230 and 240. Alternatively, a patterned mask (not shown) may be formed on the substrate 100, and then a semiconductor layer, such as a semiconductor layer including silicon germanium, may be formed on the portion of the substrate 100 exposed from the patterned mask by an epitaxial growth process, and the semiconductor layer may be the corresponding fin structures 210, 220, 230 and 240. Alternatively, the fin structures 210, 220, 230 and 240 may be formed by a sidewall image transfer (SIT) process, which is well known to those skilled in the art, the details thereof are omitted herein.

Next, an insulating structure 300 is formed on the substrate 100 and surrounding the fin structures 210, 220, 230 and 240. Each of the fin structures 210, 220, 230 and 240 includes an upper portion P1 higher than a top surface 301 of the insulating structure 300 and a lower portion P2 lower than the top surface 301 of the insulating structure 300. Each of the fin structures 210, 220, 230 and 240 includes a sidewall S1 and a sidewall S2 oppositely disposed in the second horizontal direction D2. The insulating structure 300 may be formed as follows. For example, a dielectric material is deposited on the substrate 100 and the fin structures 210, 220, 230 and 240, and then a portion of the dielectric material is removed to expose the upper portion P1 of each of the fin structures 210, 220, 230 and 240. The insulating structure 300 may be, for example, a shallow trench isolation (STI), which may be configured to provide electrical isolation function. The material of the insulating structure 300 may include a dielectric material such as silicon dioxide.

In FIG. 2, the left portion shows a schematic top view of a semi-finished semiconductor device, and the right portion from left to right shows schematic cross-sectional views taken along line B-B′ and line A-A′ in the left portion. As shown in FIG. 2, a portion of the insulating structure 300 is removed to form a recess 310 to expose at least a portion of the lower portions P2 of the fin structures 220 and 230. The recess 310 may be formed, for example, by firstly forming a patterned mask (not shown) such as photoresist on the substrate 100, then performing an etching process to remove a portion of the insulating structure 300 to form the recess 310, and then removing the patterned mask to complete the fabrication of the recess 310.

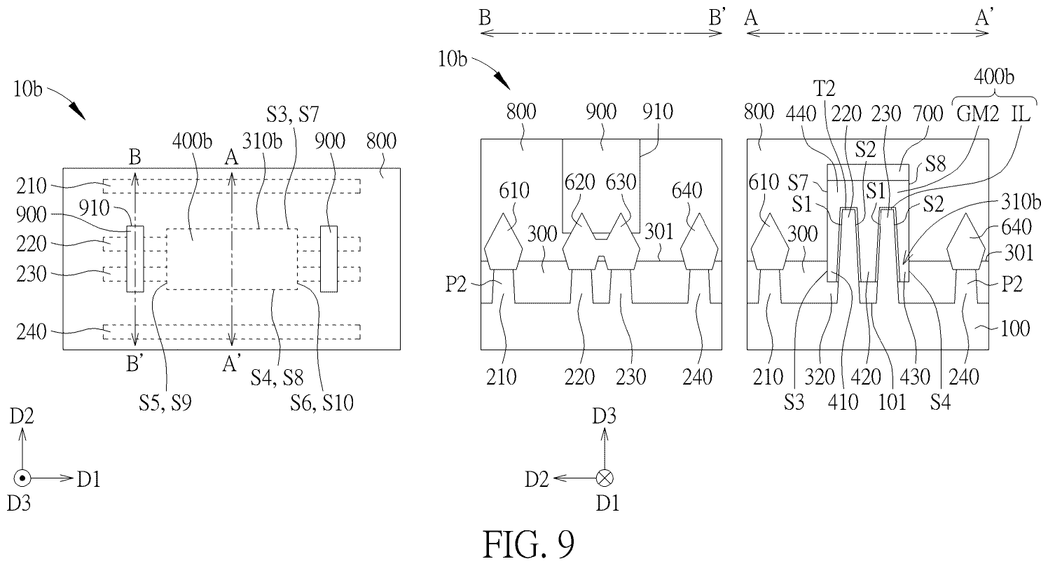

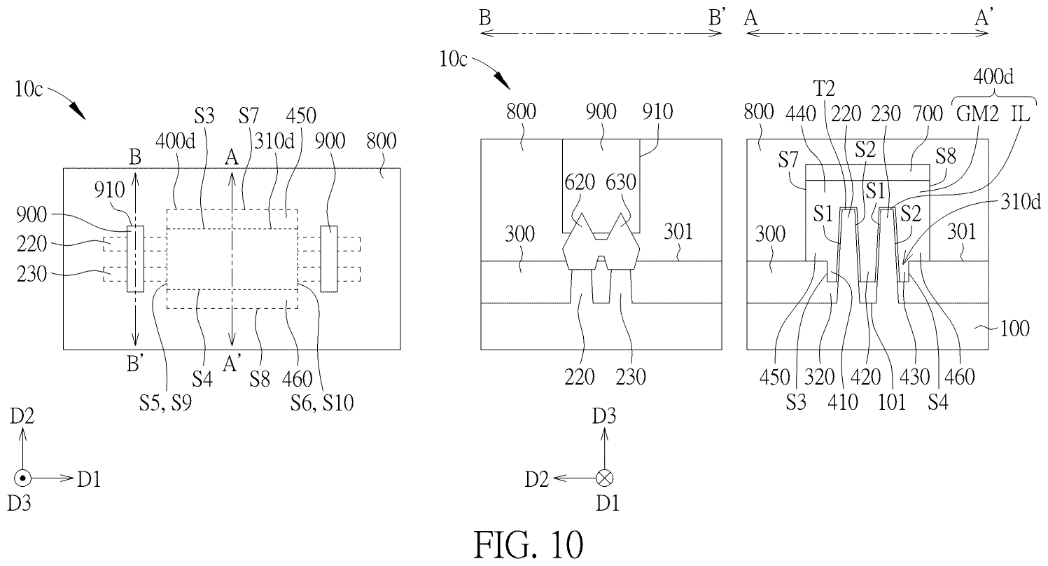

In the embodiment, the depth of the recess 310 is the same as the height of the lower portions P2, so that the lower portions P2 of the fin structures 220 and 230 located in the recess 310 are completely exposed from the recess 310. In addition, the recess 310 also exposes the top surface 101 of the substrate 100. However, the present disclosure is not limited thereto. In other embodiments, the depth of the recess 310 may be less than the height of the lower portions P2, so that the lower portions P2 of the fin structures 220 and 230 located in the recess 310 are partially exposed from the recess 310, which may refer to the relevant descriptions of FIG. 9 and FIG. 10.

In FIG. 2, in the top view of the semiconductor device (i.e., in the vertical direction D3), the fin structures 210, 220, 230 and 240 extend along a first horizontal direction D1, and the fin structures 240, 230, 220 and 210 are disposed sequentially along the second horizontal direction D2 and are spaced apart from each other. A length of each of the fin structures 210, 220, 230 and 240 in the first horizontal direction D1 is greater than a length of the recess 310 in the first horizontal direction D1, and a length of each of the fin structures 210, 220, 230 and 240 in the second horizontal direction D2 is less than a length of the recess 310 in the second horizontal direction D2. As shown in FIG. 2, in the top view of the semiconductor device, the recess 310 only overlaps a portion of each of the fin structures 220 and 230 (herein, the middle portion). That is, only the lower portion P2 of the middle portion of each of the fin structures 220 and 230 are exposed from the recess 310, and the lower portion P2 of the left portion and the lower portion P2 of the right portion of each of the fin structures 220 and 230 are completely buried in the insulating structure 300. In the top view of the semiconductor device, the recess 310 does not overlap the fin structures 210 and 240. Therefore, the lower portions P2 of the fin structures 210 and 240 are completely buried in the insulating structure 300. In the present disclosure, when an element extends along a direction, it refers that the element has a maximum length in the direction.

FIG. 3 from left to right shows schematic cross-sectional views taken along line B-B′ and line A-A′ of a semi-finished semiconductor device. FIG. 4 from left to right shows schematic cross-sectional views taken along line B-B′ and line A-A′ of a semi-finished semiconductor device. In FIG. 3 and FIG. 4, a gate structure 400′ (see FIG. 4) is formed on the fin structures 220 and 230 and in the recess 310. First, as shown in FIG. 3, a gate dielectric layer IL is formed on the fin structures 210, 220, 230 and 240 and the surface of the substrate 100 exposed from the insulating structure 300. The gate dielectric layer IL may be formed by a thermal oxidation process. Thereby, the silicon in the fin structures 210, 220, 230 and 240 and the portion of the substrate 100 not shielded by the insulating structure 300 reacts with oxygen to form the gate dielectric layer IL. The gate dielectric layer IL may include silicon dioxide.

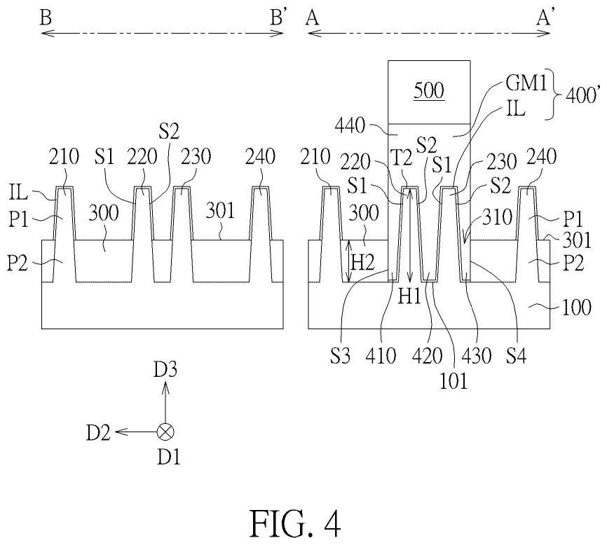

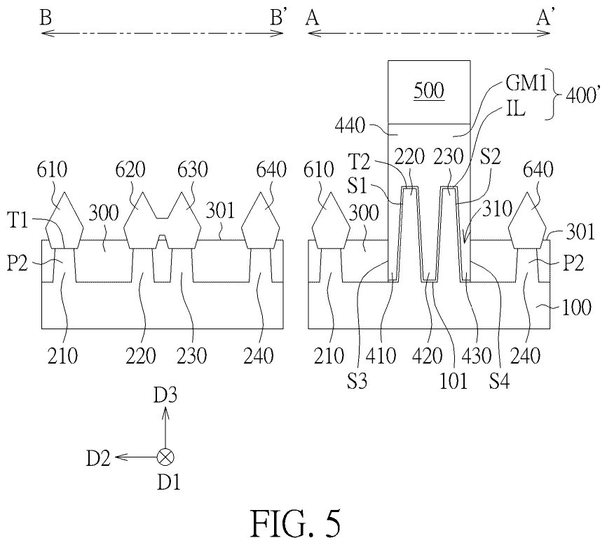

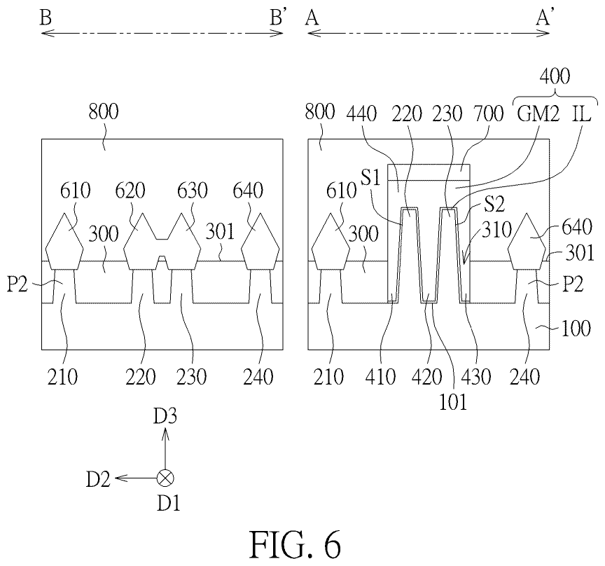

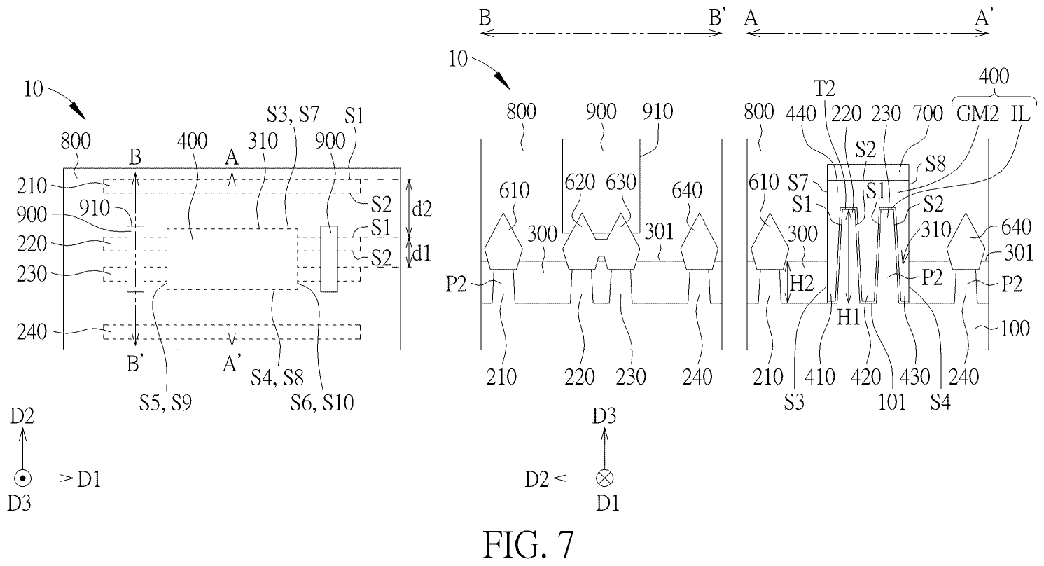

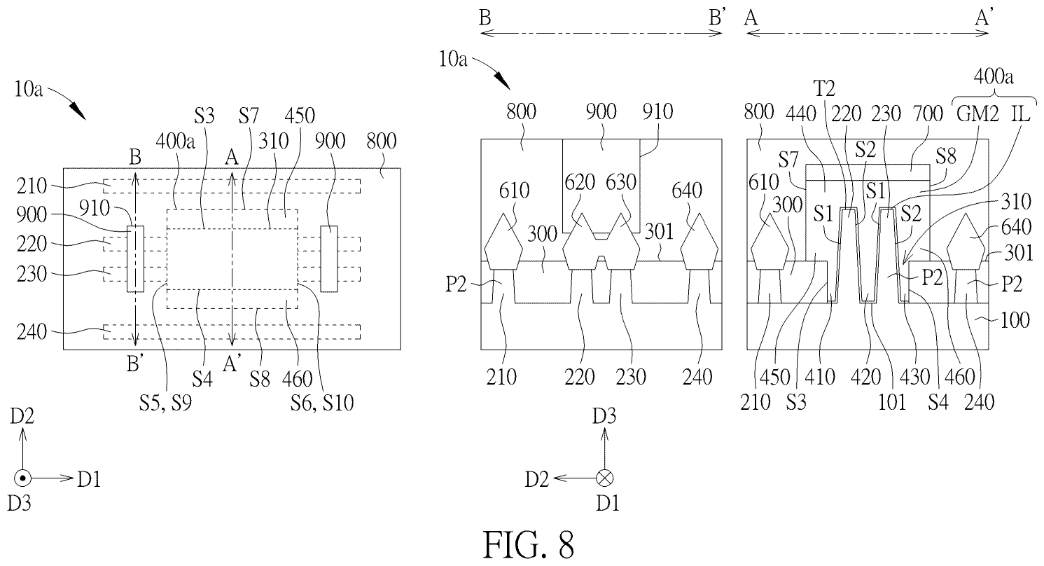

Next, as shown in FIG. 4, a gate material layer GM1 is formed in the recess 310. For example, a gate material may be formed to fully cover the gate dielectric layer IL and the insulating structure 300, and a patterned mask 500 such as photoresist may be formed on the gate material. In the embodiment, the patterned mask 500 corresponds to the range of the recess 310. In the top view of the semiconductor device, the area of the patterned mask 500 is the same as the area of the recess 310, and the patterned mask 500 completely overlaps the recess 310. Afterwards, an etching process is performed to remove a portion of the gate material (herein, the portion of the gate material outside the recess 310 is removed) to form the gate material layer GM1 to complete the fabrication of the gate structure 400′. The gate structure 400′ includes the gate dielectric layer IL and the gate material layer GM1 from bottom to top, and the patterned mask 500 is disposed on the gate structure 400′. In the top view of the semiconductor device, the area of the gate structure 400′ is the same as the area of the patterned mask 500, and the gate structure 400′ completely overlaps the patterned mask 500. Moreover, the area of the gate structure 400′ is the same as the area of the recess 310, and the gate structure 400′ completely overlaps the recess 310. However, the present disclosure is not limited thereto. In other embodiments, in the top view of the semiconductor device, the patterned mask 500 may completely overlap the recess 310, and the area of the patterned mask 500 may be greater than the area of the recess 310. That is, the range of the patterned mask 500 may cover the range of the recess 310, which may refer to the relevant descriptions of FIG. 8 and FIG. 10.

Although not shown in the drawings, before forming the gate material, a high dielectric constant (high-k) material may be optionally formed to fully cover the gate dielectric layer IL and the insulating structure 300, and then an etching process is performed to remove a portion of the gate material and a portion of the high-k material to respectively form the gate material layer GM1 and a high-k dielectric layer. In this case, the gate structure 400′ may include, from bottom to top, the gate dielectric layer IL, the high-k dielectric layer (not shown) and the gate material layer GM1. The material of the gate material layer GM1 may include amorphous silicon or polycrystalline silicon. The materials of the high-K dielectric layer may include a dielectric material with a dielectric constant greater than 3.9. Alternatively, the material of the high-K dielectric layer may include a dielectric material with a dielectric constant of 8 to 40. For example, the material of the high-K dielectric layer may include hafnium oxide (HfO), hafnium silicon oxide (HfSiO₄), hafnium silicon oxynitride (HfSiON) or aluminum oxide (Al₂O₃), and the present disclosure is not limited thereto.

In FIG. 4, the gate structure 400′ includes a first extending portion 410, a second extending portion 420, a third extending portion 430 and a connecting portion 440. The first extending portion 410 is disposed in the recess 310, and the first extending portion 410 is disposed between the insulating structure 300 and the fin structure 220. The first extending portion 410 directly contacts the sidewall S3 of the insulating structure 300 (also may be referred as the sidewall S3 of the recess 310) and the sidewall S1 of the fin structure 220, and the sidewall S1 of the fin structure 220 is higher than the sidewall S3 of the insulating structure 300. That is, the height H1 of the sidewall S1 in the vertical direction D3 is greater than the height H2 of the sidewall S3 in the vertical direction D3. The second extending portion 420 is disposed in the recess 310, and the second extending portion 420 is disposed between the fin structure 220 and the fin structure 230. The second extending portion 420 directly contacts the sidewall S2 of the fin structure 220 and the sidewall S1 of fin structure 230. The third extending portion 430 is disposed in the recess 310, and the third extending portion 430 is disposed between the fin structure 230 and the insulating structure 300. The third extending portion 430 directly contacts the sidewall S2 of the fin structure 230 and the sidewall S4 of the insulating structure 300 (also may be referred as the sidewall S4 of the recess 310), and the sidewall S2 of the fin structure 230 is higher than the sidewall S4 of the insulating structure 300. The connecting portion 440 is disposed above the top surfaces T2 of the fin structure 220 and the fin structure 230 and connects the first extending portion 410, the second extending portion 420 and the third extending portion 430. As shown in FIG. 4, the gate structure 400′ includes a comb-shaped profile.

According to an embodiment of the present disclosure, the height H1 of the sidewall S1 in the vertical direction D3 may range from 600 angstroms to 1800 angstroms, and the height H2 of the sidewall S3 in the vertical direction D3 may range from 350 angstroms to 1050 angstroms. The height H1 of the sidewall S1 in the vertical direction D3 is also equal to the height of the fin structure 220 in the vertical direction D3, and the height H2 of the sidewall S3 in the vertical direction D3 is also equal to the height of the insulating structure 300 in the vertical direction D3. According to an embodiment of the present disclosure, the maximum height of the gate structure 400′ in the vertical direction D3 may range from 1100 angstroms to 3300 angstroms.

Next, light doped drains (LDDs) (not shown) may be formed in the portions of the fin structures 210, 220, 230 and 240 exposed from the gate structure 400′, and a spacer (not shown) is formed to surround the gate structure 400′. The spacer may be a single-layer structure or a multi-layer structure. and the material of the spacer may include oxides and/or nitrides, such as silicon dioxide, silicon nitride, silicon oxynitride or silicon carbonitride. How to form the LDDs and the spacer is well known to those skilled in the art, the details thereof are omitted herein.

FIG. 5 from left to right shows schematic cross-sectional views taken along line B-B′ and line A-A′ of a semi-finished semiconductor device. As shown in FIG. 5, the portions of the fin structures 210, 220, 230 and 240 not covered by the insulating structure 300, the gate structure 400′ and the patterned mask 500 are partially removed, so that the top surfaces T1 of the portions of the fin structures 210, 220, 230 and 240 not covered by the insulating structure 300, the gate structure 400′ and the patterned mask 500 are slightly lower than the top surface 301 of the insulating structure 300, while the top surfaces T2 of the portions of the fin structures 220 and 230 covered by the insulating structure 300, the gate structure 400′ and the patterned mask 500 remain higher than the top surface 301 of the insulating structure 300. Next, a selective epitaxial growth process is performed to form epitaxial layers 610, 620, 630 and 640 on the fin structures 210, 220, 230 and 240, respectively. The epitaxial layers 610 and 640 are respectively disposed on the fin structures 210 and 240, and in the top view of the semiconductor device, the epitaxial layers 610 and 640 completely cover the fin structures 210 and 240, respectively. The epitaxial layers 620 and 630 are respectively disposed on the portions of the fin structures 220 and 230 exposed from the gate structure 400′, and the epitaxial layers 620 and 630 are connected with each other.

In the present disclosure, when forming the epitaxial layers 610, 620, 630 and 640, dopants may be implanted into the epitaxial layers 610, 620, 630 and 640 in-situ by an implanting process and an annealing process, so that the portions of the epitaxial layers 620 and 630 located at two sides of the gate structure 400′ may be served as source/drain regions (not labeled). Alternatively, the implanting process and the annealing process may be performed after the epitaxial layers 610, 620, 630 and 640 are formed, so that the portions of the epitaxial layers 620 and 630 located at two sides of the gate structure 400′ may be served as the source/drain regions. The dopants of the source/drain regions may be adjusted depending on the semiconductor device 10 (see FIG. 7) being applied to an n-type metal oxide semiconductor (NMOS) transistor or a p-type metal oxide semiconductor (PMOS) transistor. For example, when the semiconductor device 10 is applied to the NMOS transistor, the source/drain regions may be implanted with n-type impurities such as arsenic and phosphorus. When the semiconductor device 10 is applied to the PMOS transistor, the source/drain regions may be implanted with p-type impurities, such as boron and indium. Afterward, a self-aligned silicide process may be optionally performed to form a silicide (not shown) on the epitaxial layers 610, 620, 630 and 640). The silicide, for example, may include nickel silicide (NiSi), but not limited thereto. How to form the silicide is well known in the art and is not repeated herein.

FIG. 6 from left to right shows schematic cross-sectional views taken along line B-B′ and line A-A′ of a semi-finished semiconductor device. As shown in FIG. 6, a replacement metal gate (RMG) process may be performed to replace the gate material layer GM1 with the metal gate material layer GM2. For example, a dielectric material may be firstly formed to cover the insulating structure 300, the epitaxial layers 610, 620, 630 and 640, the gate structure 400′ and the patterned mask 500. Next, a planarization process may be performed to remove a portion of the dielectric material and the patterned mask 500, so that the remaining dielectric material is aligned with the top surface of the gate structure 400′. Next, the gate material layer GM1 in FIG. 5 is replaced with the metal gate material layer GM2 to form the gate structure 400. Next, a self-aligned silicide process may be optionally performed to form a silicide 700 on the gate structure 400. The silicide 700, for example, may include nickel silicide (NiSi). Next, a dielectric material is deposited on the silicide 700, and a planarization process is performed to complete the fabrication of the dielectric layer 800. The material of the dielectric layer 800 may include silicon dioxide or tetraethoxysilane (TEOS), but not limited thereto. The metal gate material layer GM2 may be a single-layer structure or a multi-layer structure (not shown). For example, the metal gate material layer GM2 may include a low-resistance metal layer, and the material of the low-resistance metal layer may include, for example, copper (Cu), aluminum (Al), tungsten (W), titanium aluminum alloy (TiAl), cobalt tungsten phosphide (CoWP) or a combination thereof. The metal gate material layer GM2 may further include layers, such as barrier layers and work function metal layers depending on the semiconductor device 10 (see FIG. 7) being applied to an NMOS transistor or a PMOS transistor.

In FIG. 7, the left portion shows a schematic top view of a semiconductor device 10, and the right portion from left to right shows schematic cross-sectional views taken along line B-B′ and line A-A′ of the semiconductor device 10. For the sake of simplification, only the fin structures 210, 220, 230 and 240, the gate structure 400, the contact structures 900, the holes 910 and the dielectric layer 800 are shown in the top view of the semiconductor device 10, and other elements are omitted. As shown in FIG. 7, the contact structures 900 are formed on the epitaxial layers 220 and 230 and are electrically connected with the epitaxial layers 220 and 230. For example, semiconductor processes, such as photolithography process and etching process, may be performed to remove a portion of the dielectric layer 800 to form the holes 910 to expose portions of the epitaxial layers 620 and 630, and then a conductive material is filled in the holes 910. Afterward, a planarization process is performed to form the contact structures 900 in the dielectric layer 800. The contact structures 900 may be slot contacts. Each of the contact structures 900 may include a barrier layer (not shown) and a metal layer (not shown). The material of the barrier layer may include titanium, tantalum, titanium nitride, tantalum nitride, nitrogen or a combination thereof. The material of the metal layer may include aluminum, titanium, tantalum, tungsten, niobium, molybdenum, copper, or a combination thereof, but not limited thereto. Thereby, the fabrication of the semiconductor device 10 may be completed.

The aforementioned film layers, such as the insulating structure 300, the gate material layer GM1, the metal gate material layer GM2, and the dielectric layer 800, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

In FIG. 7, the semiconductor device 10 includes the fin structures 210, 220, 230 and 240, the insulating structure 300 and the gate structure 400. The fin structures 210, 220, 230 and 240 are disposed on the substrate 100. The insulating structure 300 is disposed on the substrate 100 and surrounds the fin structures 210, 220, 230 and 240. Each of the fin structures 220 and 230 includes the lower P2 lower than the top surface 301 of the insulating structure 300. The insulating structure 300 is formed with the recess 310 to expose at least a portion of each of the lower portions P2 of the fin structures 220 and 230. In the embodiment, the depth of the recess 310 is the same as the height of the lower portion P2, so that the lower portions P2 of the fin structures 220 and 230 located in the recess 310 are completely exposed from the recess 310. The gate structure 400 is disposed on the fin structures 220 and 230 and in the recess 310. The gate structure 400 includes a first extending portion 410 disposed between the fin structure 220 and the insulating structure 300. The first extending portion 410 directly contacts the sidewall S1 of the fin structure 220 and the sidewall S3 of the insulating structure 300, and the sidewall S1 of the fin structure 220 is higher than the sidewall S3 of the insulating structure 300. That is, the height H1 of the sidewall S1 in the vertical direction D3 is greater than the height H2 of the sidewall S3 in the vertical direction D3.

The gate structure 400 may further include a second extending portion 420, a third extending portion 430 and a connecting portion 440. The second extending portion 420 is disposed between the fin structures 220 and 230, and the second extending portion 420 directly contacts the sidewall S2 of the fin structure 220 and the sidewall S1 of the fin structure 230. The third extending portion 430 is disposed in the recess 310, and the third extending portion 430 is disposed between the fin structure 230 and the insulating structure 300. The third extending portion 430 directly contacts the sidewall S2 of the fin structure 230 and the sidewall S4 of the insulating structure 300, and the sidewall S2 of the fin structure 230 is higher than the sidewall S4 of the insulating structure 300. The connecting portion 440 is disposed above the top surfaces T2 of the fin structures 220 and 230 and is connected with the first extending portion 410, the second extending portion 420 and the third extending portion 430. The first extending portion 410, the second extending portion 420 and the third extending portion 430 are disposed in the recess 310. As shown in FIG. 7. the gate structure 400 includes a comb-shaped profile.

The gate structure 400 includes the gate dielectric layer IL and the metal gate material layer GM2 from bottom to top. The recess 310 exposes the top surface 101 of the substrate 100, and the gate structure 400 directly contacts the top surface 101 of the substrate 100. In the top view of the semiconductor device 10, the gate structure 400 completely overlaps the recess 310, and the sidewalls S3, S4, S5 and S6 of the recess 310 are respectively aligned with the sidewalls S7, S8, S9 and S10 of the gate structure 400. In this case, the area of the gate structure 400 is equal to the area of the recess 310.

The semiconductor device 10 may further include the silicide 700, the epitaxial layers 610, 620, 630 and 640, the dielectric layer 800 and the contact structures 900. The silicide 700 is disposed on the gate structure 400. The epitaxial layers 610 and 640 are respectively disposed on the fin structures 210 and 240. The epitaxial layers 620 and 630 are respectively disposed on the portions of the fin structures 220 and 230 exposed from the gate structure 400. In addition, the epitaxial layers 620 and 630 are connected with each other. The dielectric layer 800 covers the epitaxial layers 610, 620, 630 and 640, the insulating structure 300, the gate structure 400 and the silicide 700.

The contact structures 900 are disposed on the epitaxial layers 620 and 630 and are electrically connected with the epitaxial layers 620 and 630. The contact structures 900 are not disposed on the epitaxial layers 610 and 640. Therefore, the fin structures 210 and 240 are dummy fin structures. The lower portions P2 of the fin structures 210 and 240 are lower than the top surface 301 of the insulating structure 300, and the lower portions P2 of the fin structures 210 and 240 are completely buried in the insulating structure 300. More specifically, the insulating structure 300 is disposed between the gate structure 400 and the fin structures 210 and 240 which are served as the dummy fin structures. The insulating structure 300 can provide electrical isolation function between the fin structures 210 and 240 and the gate structure 400, which can prevent the fin structures 210 and 240 from being turned on when the gate structure 400 is turned on. In this embodiment, the number of the fin structures disposed below the gate structure 400 is two (i.e., the fin structures 220 and 230). However, it is only exemplary and can be flexibly adjusted according to actual needs. For example, the number of the fin structure disposed below the gate structure 400 may be one to twelve, but not limited thereto.

In the top view of the semiconductor device 10, a distance d1 is between the fin structure 220 and the fin structure 230, a distance d2 is between the fin structure 220 and the fin structure 210, and a following condition may be satisfied: d2=N×d1, in which N is an integer greater than or equal to 2. Thereby, the effect of electrical isolation between the fin structure 220 and the fin structure 210 serving as the dummy fin structure can be improved. The aforementioned sentence of “a distance d1 is between the fin structure 220 and the fin structure 230” may refer the distance between the same sidewalls of the fin structure 220 and the fin structure 230 (i.e., the distance between the sidewall S1 of the fin structure 220 and the sidewall S1 of the fin structure 230 or the distance between the sidewall S2 of the fin structure 220 and the sidewall S2 of the fin structure 230) in the second horizontal direction D2 perpendicular to the extending direction thereof or the distance between the center lines (not shown) of the fin structure 220 and the fin structure 230 in the second horizontal direction D2 perpendicular to the extending direction thereof. Similarly, the aforementioned sentence of “a distance d2 is between the fin structure 220 and the fin structure 210” may refer the distance between the same sidewalls of the fin structure 220 and the fin structure 210 (i.e., the distance between the sidewall S1 of the fin structure 220 and the sidewall S1 of the fin structure 210 or the distance between the sidewall S2 of the fin structure 220 and the sidewall S2 of the fin structure 210) in the second horizontal direction D2 perpendicular to the extending direction thereof or the distance between the center lines (not shown) of the fin structure 220 and the fin structure 210 in the second horizontal direction D2 perpendicular to the extending direction thereof.

In the top view of the semiconductor device 10, the fin structures 210, 220, 230 and 240 may extend along the first horizontal direction D1, the contact structures 900 may extend along the second horizontal direction D2, and the first horizontal direction D1 is perpendicular to the second horizontal direction D2. Furthermore, the two contact structures 900 are respectively disposed at two sides of the gate structure 400 along the first horizontal direction D1.

As shown in FIG. 7, when the height of the semiconductor device 10 is fixed, with the gate structure 400 being disposed in the recess 310, it is beneficial to increase the height of the gate structure 400 and improve the ability of the gate structure 400 to control the current. Accordingly, the gate structure 400 can effectively control on and off of the transistor (not labeled), which is beneficial to reduce the noise of the semiconductor device 10.

FIG. 8 is a schematic view of a semiconductor device 10a according to another embodiment of the present disclosure. In FIG. 8, the left portion shows a schematic top view of the semiconductor device 10a, and the right portion from left to right shows schematic cross-sectional views taken along line B-B′ and line A-A′ of the semiconductor device 10a. For the sake of simplification, only the fin structures 210, 220, 230 and 240, the gate structure 400a, the contact structures 900, the holes 910 and the dielectric layer 800 are shown in the top view of the semiconductor device 10a, and other elements are omitted. The main difference between the semiconductor device 10a and the semiconductor device 10 is that the gate structure 400a is different from the gate structure 400. The gate structure 400a further includes a first lateral extending portion 450 and a second lateral extending portion 460. The first lateral extending portion 450 is connected with the first extending portion 410 and extends outwardly in the second horizontal direction D2. The second lateral extending portion 460 is connected with the third extending portion 430 and extends outwardly in the second horizontal direction D2. The connecting portion 440 is disposed above the top surfaces T2 of the fin structure 220 and the fin structure 230 and is connected with the first lateral extending portion 450, the first extending portion 410, the second extending portion 420, the third extending portion 430 and the second lateral extending portion 460. The first lateral extending portion 450 and the second lateral extending portion 460 are disposed on the insulating structure 300 and directly contact the top surface 301 of the insulating structure 300. In other words, in this embodiment, the gate structure 400a directly contacts the top surface 301 of the insulating structure 300.

In the top view of the semiconductor device 10a, the gate structure 400a overlaps the recess 310, and the gate structure 400a completely covers the recess 310. Specifically, the sidewalls S3 and S4 of the recess 310 are located within the range of the gate structure 400a. The sidewalls S5 and S6 of the recess 310 (also may be referred as the sidewalls S5 and S6 of the insulating structure 300) are aligned with the sidewalls S9 and S10 of the gate structure 400a, respectively. In this case, the area of the gate structure 400a is greater than the area of the recess 310. Thereby, it is beneficial to reduce the requirement for aligning the gate structure 400a and the recess 310. In other embodiments, the sidewalls S5 and S6 of the recess 310 may also located within the range of the gate structure 400a, which can further reduce the requirement for aligning the gate structure 400a and the recess 310.

In FIG. 8, the lengths of the first lateral extending portion 450 and the second lateral extending portion 460 in the second horizontal direction D2 are the same. However, it is only exemplary. The lengths of the first lateral extending portion 450 and the second lateral extending portion 460 in the second horizontal direction D2 may be different.

FIG. 9 is a schematic view of a semiconductor device 10b according to another embodiment of the present disclosure. In FIG. 9, the left portion shows a schematic top view of the semiconductor device 10b, and the right portion from left to right shows schematic cross-sectional views taken along line B-B′ and line A-A′ of the semiconductor device 10b. For the sake of simplification, only the fin structures 210, 220, 230 and 240, the gate structure 400b, the contact structures 900, the holes 910 and the dielectric layer 800 are shown in the top view of the semiconductor device 10b, and other elements are omitted. The main difference between the semiconductor device 10b and the semiconductor device 10 is that the depth of the recess 310b is different from the depth of the recess 310, and the height of the gate structure 400b is different from the height of the gate structure 400.

Specifically, when forming the recess 310b, the depth of the recess 310b is controlled to be smaller than the height of the lower portion P2 of each of the fin structures 220 and 230, so that only a portion of each of the lower portions P2 of the fin structures 220 and 230 in the recess 310b is exposed from the recess 310b. In this case, the insulating structure 300 may include a reserved portion 320 disposed below the recess 310b, so that the recess 310b does not expose the top surface 101 of the substrate 100. Thereby, it is beneficially to reduce the probability of current leakage.

FIG. 10 is a schematic view of a semiconductor device 10c according to another embodiment of the present disclosure. In FIG. 10, the left portion shows a schematic top view of the semiconductor device 10c, and the right portion from left to right shows schematic cross-sectional views taken along line B-B′ and line A-A′ of the semiconductor device 10c. For the sake of simplification, only the fin structures 220 and 230, the gate structure 400d, the contact structures 900, the holes 910 and the dielectric layer 800 are shown in the top view of the semiconductor device 10c, and other elements are omitted. The main difference between the semiconductor device 10c and the semiconductor device 10a shown in FIG. 8 is that the depth of the recess 310d is different from the depth of the recess 310, and the height of the gate structure 400d is different from the height of the gate structure 400a. In addition, the semiconductor device 10c does not include the fin structures 210 and 240 and the epitaxial layers 610 and 640. In other words, the fin structures 210 and 240 which serve as the dummy fin structures in the semiconductor devices 10, 10a, and 10b are optional.

Specifically, when forming the recess 310d, the depth of the recess 310d is controlled to be smaller than the height of the lower portion P2 of each of the fin structures 220 and 230, so that only a portion of each of the lower portions P2 of the fin structures 220 and 230 in the recess 310d is exposed from the recess 310d. In this case, the insulating structure 300 may include a reserved portion 320 disposed below the recess 310d, so that the recess 310d does not expose the top surface 101 of the substrate 100. Thereby, it is beneficially to reduce the probability of current leakage.

Compared with the prior art, in the present disclosure, with the first fin structure being disposed on the substrate, forming the recess in the insulating structure surrounding the first fin structure, and disposing the gate structure on the first fin structure and the recess, it is beneficial to increase the height of the gate structure in a limited volume, so that the ability of the gate to control current may be enhanced. Accordingly, the gate structure can effectively control on and off of the transistor, which is beneficial to reduce noises of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first fin structure disposed on a substrate;
an insulating structure disposed on the substrate and surrounding the first fin structure; and
a gate structure disposed on the first fin structure, wherein the gate structure comprises a first extending portion disposed between the first fin structure and the insulating structure.

2. The semiconductor device of claim 1, wherein the first fin structure comprises a lower portion lower than a top surface of the insulating structure, and the insulating structure is formed with a recess to expose at least a portion of the lower portion of the first fin structure.

3. The semiconductor device of claim 1, wherein the first extending portion directly contacts a sidewall of the first fin structure and a sidewall of the insulating structure, and the sidewall of the first fin structure is higher than the sidewall of the insulating structure.

4. The semiconductor device of claim 2, wherein the insulating structure comprises a reserved portion disposed below the recess.

5. The semiconductor device of claim 2, wherein the recess exposes the substrate, and the gate structure directly contacts the substrate.

6. The semiconductor device of claim 1, wherein the gate structure directly contacts a top surface of the insulating structure.

7. The semiconductor device of claim 2, further comprising:
a second fin structure disposed at a side of the first fin structure, wherein the second fin structure comprises a lower portion lower than the top surface of the insulating structure, the recess exposes at least a portion of the lower portion of the second fin structure, and the gate structure is further disposed on the second fin structure.

8. The semiconductor device of claim 7, further comprising:
a first epitaxial layer disposed on a portion of the first fin structure exposed from the gate structure; and
a second epitaxial layer disposed on a portion of the second fin structure exposed from the gate structure, wherein the first epitaxial layer and the second epitaxial layer are connected with each other.

9. The semiconductor device of claim 8, further comprising:
a contact structure disposed on the first epitaxial layer and the second epitaxial layer and electrically connected with the first epitaxial layer and the second epitaxial layer.

10. The semiconductor device of claim 9, wherein in a top view of the semiconductor device, the first fin structure and the second fin structure extend along a first horizontal direction, the contact structure extends along a second horizontal direction, and the first horizontal direction is perpendicular to the second horizontal direction.

11. The semiconductor device of claim 2, wherein in a top view of the semiconductor device, the gate structure overlaps the recess, and an area of the gate structure is greater than or equal to an area of the recess.

12. The semiconductor device of claim 7, further comprising:
a third fin structure disposed at another side of the first fin structure, wherein the third fin structure comprises a lower portion lower than the top surface of the insulating structure, and the lower portion of the third fin structure is completely buried in the insulating structure.

13. The semiconductor device of claim 12, wherein a distance d1 is between the first fin structure and the second fin structure, a distance d2 is between the first fin structure and the third fin structure, and a following condition is satisfied:
d2=N×d1, wherein N is an integer greater than or equal to 2.

14. The semiconductor device of claim 12, wherein the third fin structure is a dummy fin structure.

15. A method for fabricating a semiconductor device, comprising:
forming a first fin structure on a substrate;
forming an insulating structure on the substrate and surrounding the first fin structure; and
forming a gate structure on the first fin structure, wherein the gate structure comprises a first extending portion disposed between the first fin structure and the insulating structure.

16. The method of claim 15, wherein the gate structure directly contacts a top surface of the insulating structure.

17. The method of claim 15, further comprising:
forming a second fin structure at a side of the first fin structure;
forming the insulating structure on the substrate and surrounding the second fin structure, wherein the second fin structure comprises a lower portion lower than a top surface of the insulating structure; and
forming the gate structure on the second fin structure.

18. The method of claim 17, further comprising:
forming a first epitaxial layer on a portion of the first fin structure exposed from the gate structure; and
forming a second epitaxial layer on a portion of the second fin structure exposed from the gate structure, wherein the first epitaxial layer and the second epitaxial layer are connected with each other.

19. The method of claim 18, further comprising:
forming a contact structure on the first epitaxial layer and the second epitaxial layer and electrically connected with the first epitaxial layer and the second epitaxial layer.

20. The method of claim 17, further comprising:
forming a third fin structure at another side of the first fin structure; and
forming the insulating structure on the substrate and surrounding the third fin structure, wherein the third fin structure comprises a lower portion lower than the top surface of the insulating structure, and the lower portion of the third fin structure is completely buried in the insulating structure.
